(19) United States
(12) Patent Application Publication
(10) Pub. No.: US 2011/0031549 A1
(43) Pub. Date: Feb. 10, 2011

(54) SEMICONDUCTOR MEMORY DEVICE AND MANUFACTURING METHOD OF SEMICONDUCTOR MEMORY DEVICE

(75) Inventors: Masaki Kondo, Kawasaki-shi (JP); Kazuaki Isobe, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/848,363

(22) Filed: Aug. 2, 2010

(30) Foreign Application Priority Data
Aug. 4, 2009 (JP) 2009-181798

(51) Int. Cl. H01L 27/115; H01L 21/8247; H01L 29/788

(52) U.S. Cl. 257/321; 438/594; 438/257; 257/E21.68; 257/E27.103; 257/E29.3

(57) ABSTRACT

A memory includes active areas and an isolation on a semiconductor substrate. A tunnel dielectric film is on active areas. Floating gates include lower gate parts and upper gate parts. An upper gate part has a larger width than that of a lower gate part on a cross section perpendicular to an extension direction of an active area, and is provided on the lower gate part. An intermediate dielectric film is on an upper surface and a side surface of each floating gate. The control gate is on an upper surface and a side surface of each floating gate via the intermediate dielectric film. A height of a lower end of each control gate from a surface of the semiconductor substrate is lower than a height of an interface between the upper gate part and the lower gate part from the surface of the semiconductor substrate.

### CROSS REFERENCE TO RELATED APPLICATIONS

This application is based upon and claims the benefit of priority from the prior Japanese Patent Application No. 2009-181798, filed on Aug. 4, 2009, the entire contents of which are incorporated herein by reference.

### FIELD

The embodiments of the present invention relate to a semiconductor memory device and a manufacturing method thereof.

### BACKGROUND

As one of most important references indicating memory performance of a NAND flash memory or a NOR flash memory, there is a coupling ratio (Cipd/Cfg). The coupling ratio is a value obtained by dividing a capacitance Cipd between a floating gate and a control gate by a total floating gate capacitance Cfg. When the coupling ratio is increased, a writing speed and an erasing speed become fast.

Conventionally, increasing an opposing area of the control gate and the floating gate is considered in order to increase the coupling ratio. Embedding the control gate into between floating gates is considered in order to increase the opposing area of the control gate and the floating gate. Further, increasing an area of an upper surface or a side surface of the floating gate is considered in order to increase the coupling ratio.

However, when an area of an upper surface of the floating gate is increased, this results in an increase in a size of a memory cell and a size of a chip. When an area of a side surface of the floating gate is increased, a capacitance between floating gates of memory cells adjacent in a bit line direction increases in the NAND flash memory, and a capacitance between the floating gate and a bit line contact and a capacitance between the floating gate and a source line contact increase in the NOR flash memory. Therefore, when an area of a side surface of a floating gate is increased, not only Cipd but also Cfg increases. When both Cipd and Cfg increase, the coupling ratio does not easily increase.

### BRIEF DESCRIPTION OF THE DRAWINGS

FIG. 1 is a circuit diagram showing a configuration of a NOR flash memory according to a first embodiment;

FIGS. 2 and 3 are cross-sectional views of a configuration of memory cells MC of the NOR flash memory according to the first embodiment;

FIG. 4 is a graph showing a relationship between the depth D1 of the lower end LEcg of the control gate CG protruding from the interface IF to the silicon substrate 10 and a coupling ratio between the floating gate FG and the control gate CG;

FIG. 5A to FIG. 6C are cross-sectional views showing a manufacturing method according to the first embodiment;

FIG. 7 is a cross-sectional view showing a manufacturing method according to a modification of the first embodiment;

FIG. 8 is a cross-sectional view of a configuration of a NOR flash memory according to a second embodiment;

FIG. 9 is a cross-sectional view showing a configuration of a NOR flash memory according to a third embodiment;

FIG. 10 is a cross-sectional view showing a configuration of a NOR flash memory according to a fourth embodiment;

FIG. 11A to FIG. 11E are cross-sectional views showing a manufacturing method of the NOR flash memory according to the fourth embodiment;

FIG. 12 is a circuit diagram showing an example of a configuration of a NAND flash memory; and

FIG. 13 is a cross-sectional view showing an example of a configuration of a NAND flash memory.

### DETAILED DESCRIPTION

A semiconductor memory device according to the present embodiments includes plural active areas formed on a surface of a semiconductor substrate. An element isolation part is provided between adjacent active areas. A tunnel dielectric film is provided on active areas. Each of plural floating gates includes a lower gate part and an upper gate part. The lower gate part faces each active area via the tunnel dielectric film. The upper gate part has a larger width than that of the lower gate part on a cross section perpendicular to an extension direction of an active area, and is provided on the lower gate part. An intermediate dielectric film is provided on an upper surface and a side surface of each floating gate. The control gate is provided on an upper surface and a side surface of at least each floating gate via the intermediate dielectric film. A height of a lower end of each control gate from a surface of the semiconductor substrate is lower than a height of an interface between the upper gate part and the lower gate part from the surface of the semiconductor substrate.

The embodiments will now be explained with reference to the accompanying drawings.

### First Embodiment

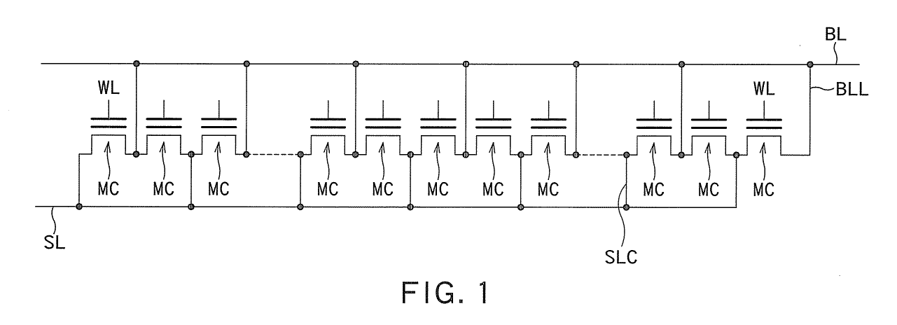

FIG. 1 is a circuit diagram showing a configuration of a NOR flash memory according to a first embodiment. In the NOR flash memory, each memory cell MC is connected to a source line SL and a bit line BL via a source line contact SLC and a bit line contact BLC, respectively. Adjacent memory cells MC alternately share a source line contact SLC or a bit line contact BLC. Accordingly, plural memory cells MC are connected in series.

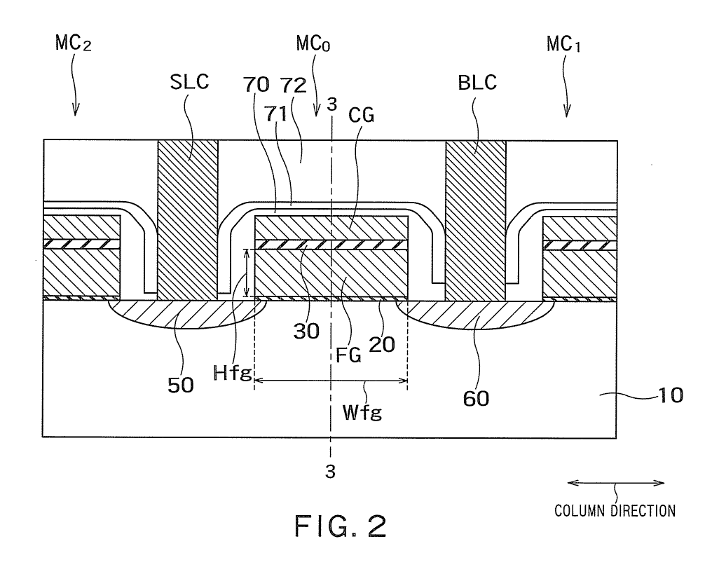

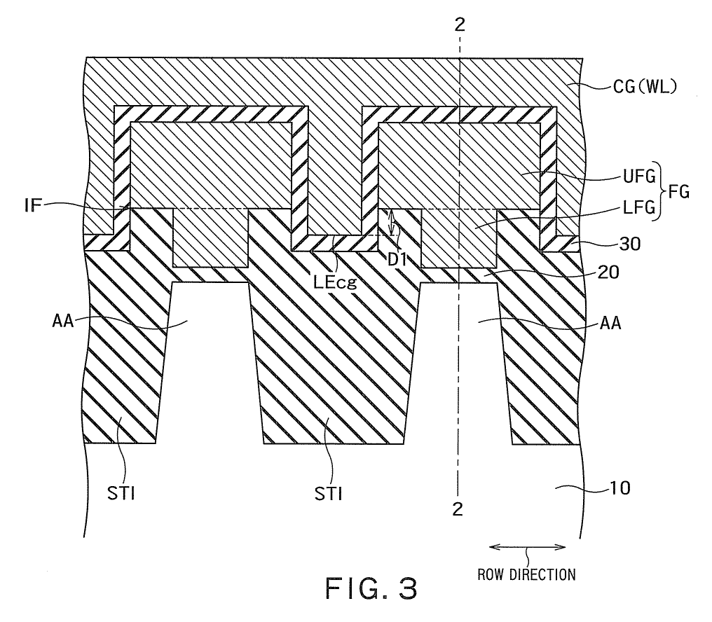

FIGS. 2 and 3 are cross-sectional views of a configuration of memory cells MC of the NOR flash memory according to the first embodiment. FIG. 2 is a cross-sectional view along an extension direction (hereinafter, “column direction”) of the bit line BL, and shows a cross-sectional surface along a line 2-2 in FIG. 3. FIG. 3 is a cross-sectional view along an extension direction (hereinafter, “row direction”) of a word line WL, and shows a cross-sectional surface along a line 3-3 in FIG. 2.

As shown in FIG. 3, plural active areas AA are formed on a surface of a silicon substrate 10. An element isolation part STI (Shallow Trench Isolation) is provided between active areas AA adjacent to each other. Each active area AA is extended to a column direction. Therefore, the element isolation part STI is also extended to a column direction between active areas AA.

A tunnel dielectric film 20 is provided in the active areas AA.

A floating gate FG is provided on each active area AA via the tunnel dielectric film 20. On a cross-sectional surface (a cross-sectional surface shown in FIG. 3) in a direction perpendicular to a column direction, the floating gate FG is formed in a T shape. More specifically, the floating gate FG includes a lower gate part LFG and an upper gate part UFG. The lower gate part LFG faces the active area AA via the tunnel dielectric film 20. In the cross-sectional surface shown in FIG. 3, a width of a bottom side of the lower gate part LFG is substantially equal to a width of an upper side of the active area AA. The upper gate part UFG is provided on the lower gate part LFG, and has a larger width than that of the lower gate part LFG on the cross-sectional surface shown in FIG. 3.

An intermediate dielectric film (IPD (Inter Poly-silicon Dielectric)) 30 is provided on an upper surface and a side surface of each floating gate FG.

A control gate CG is provided to face an upper surface and a side surface of each floating gate FG via the intermediate dielectric film 30. The control gate CG is provided not only on the floating gate FG but also between floating gates FG adjacent in a row direction. A lower end LEcg of the control gate CG is nearer to the silicon substrate 10 than an interface IF between the upper gate part UFG and the lower gate part LFG. This means that a height of the lower end LEcg from a surface of the silicon substrate 10 is lower than a height of the interface IF from the surface of the silicon substrate 10. That is, the control gate CG protrudes into the inside of the element isolation part STI deeper (lower) than the interface IF between the upper gate part UFG and the lower gate part LFG. The lower end LEcg of the control gate CG is inside the element isolation part STI by a depth D1 from the interface IF.

As shown in FIG. 2, the control gate CG and the floating gate FG are covered by protection films 70 and 71. An interlayer dielectric film 72 is provided on the protection films 70 and 71. A memory cell MC₀ shares a drain layer 60 and the bit line contact BLC with a memory cell MC₁ adjacent to the MCₒ on a drain's side of the MCₒ. Further, the memory cell MC₀ shares a source layer 50 and the source line contact SLC with a memory cell MC₂ adjacent to the MCₒ on a source's side of the MC₀. In the NOR flash memory, the bit line contact BLC is adjacent to one side surface of the floating gate FG in a column direction, and the source line contract SLC is adjacent to the other side surface of the floating gate FG.

The bit line contact BLC is connected to the drain layer 60 through the interlayer dielectric film 72 and the protection films 70 and 71, thereby electrically connecting the drain layer 60 to the bit line BL. The source line contact SLC is connected to the source layer 50 through the interlayer dielectric film 72 and the protection films 70 and 71, thereby electrically connecting the source layer 50 to the source line SL.

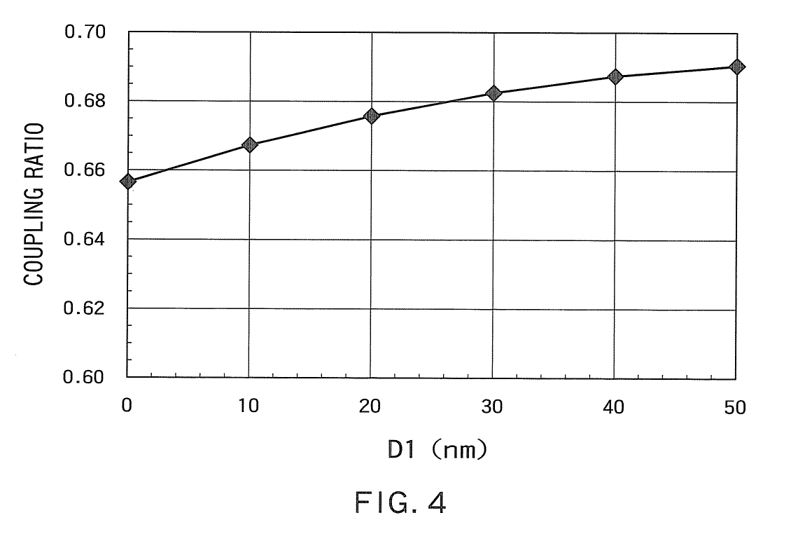

FIG. 4 is a graph showing a relationship between the depth D1 of the lower end LEcg of the control gate CG protruding from the interface IF to the silicon substrate 10 and a coupling ratio between the floating gate FG and the control gate CG.

When the depth D1 is smaller than 0 (not shown), the lower end LEcg of the control gate CG is not inside the element isolation part STI between the floating gates FG. This corresponds to a conventional structure.

In the first embodiment, D1 is larger than 0, and the lower end LEcg of the control gate CG is inside the element isolation part STI between the floating gates FG. It is clear that a coupling ratio (Cipd/Cfg) between the control gate CG and the floating gate FG can be effectively increased by this arrangement. Because a configuration of only the control gate CG is changed without changing a configuration of the floating gate FG, the capacitance Cipd between the floating gate and the control gate can be increased while suppressing an increase in the total capacitance Cfg of the floating gate FG.

In the first embodiment, although the lower end LEcg of the control gate CG is inserted deep into the element isolation part STI, a surface area of the floating gate FG or the control gate CG is not increased. Therefore, a chip size is not increased. That is, in the first embodiment, a coupling ratio (Cipd/Cfg) between the control gate CG and the floating gate FG can be effectively increased without increasing a chip size.

Further, in the first embodiment, an area of a side surface of the floating gate FG is not increased. Therefore, a capacitance between the floating gate FG and the bit line contact BLC and a capacitance between the floating gate FG and the source line contact SLC are not increased.

In a simulation shown in FIG. 4, for example, when the depth D1 is 30 nm, the coupling ratio (Cipd/Cfg) becomes larger than that of a conventional structure (D1=0) by about 4%. A data erasing speed becomes faster by about ten times when the coupling ratio becomes larger by 4%.

As described above, according to the first embodiment, a data erasing speed or a data writing speed can be improved without increasing a chip size and without deteriorating reliability.

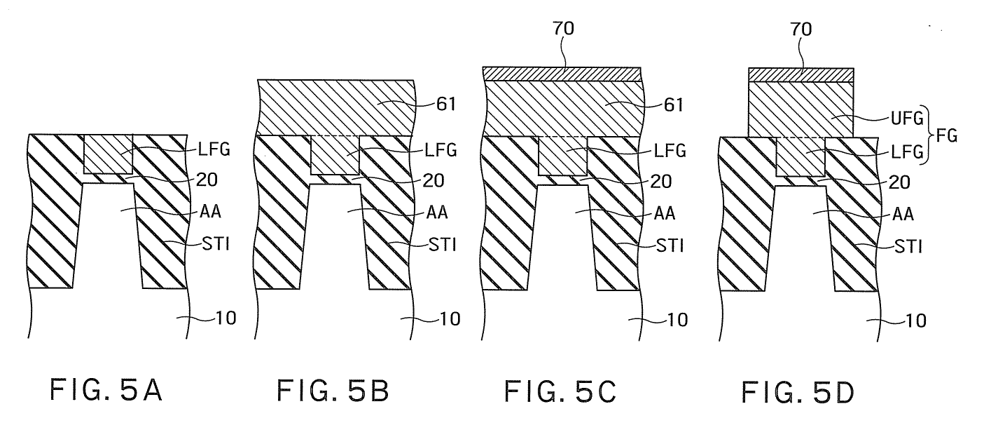

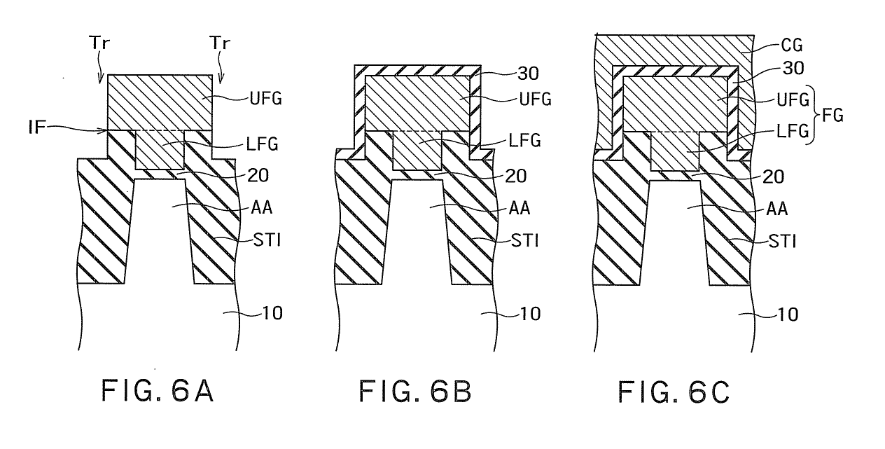

A manufacturing method according to the first embodiment is explained with reference to FIG. 5A to FIG. 6C. FIG. 5A to FIG. 6C are cross-sectional views showing a manufacturing method of the NOR flash memory according to the first embodiment. FIG. 5A to FIG. 6C show only a cross-sectional surface of one active area AA.

First, as shown in FIG. 5A, plural active areas AA are formed on the surface of the silicon substrate 10. The element isolation part STI is formed by embedding an insulation material such as a silicon oxide film between active areas AA adjacent in a row direction. In this case, a surface of the element isolation part STI is higher than an upper surface of each active area AA, and the upper surface of the active area AA is covered by an insulation material.

The insulation material on each active area AA is then removed by using lithography and RIE (Reactive Ion Etching). The tunnel dielectric film 20 is formed by oxidizing a surface of the active area AA.

Next, a material of the floating gate FG, such as polysilicon, is deposited on the tunnel dielectric film 20 and the element isolation part STI. The material of the floating gate FG is polished by a CMP (Chemical Mechanical Polishing) until when the upper surface of the element isolation part STI is exposed. Accordingly, the lower gate part LFG as a part of the floating gate FG is formed on the tunnel dielectric film 20 as shown in FIG. 5A.

The material 61 of the floating gate FG is then deposited on the element isolation part STI and the lower gate part LFG as shown in FIG. 5B. A material 61 of the floating gate FG deposited at this time can be the same as a material of the lower gate part LFG.

A masking material 70 is then deposited on the material 61 of the floating gate FG as shown in FIG. 5C. The masking material 70 is a silicon nitride film, for example. The masking material 70 is processed into a pattern of the floating gate FG using the lithography and the RIE. At this time, the masking material 70 is patterned to have a larger width than that of the lower gate part LFG on a cross-sectional surface in a row direction. The material 61 of the floating gate FG is etched by the RIE by using the masking material 70 as a mask. Accordingly, the upper gate part UFG is formed as shown in FIG. 5D.

The element isolation part STI is then anisotropically etched by the RIE to a deeper position than that of the interface IF between the upper gate part UFG and the lower gate part LFG by using the masking material 70 as a mask. Accordingly, a trench Tr is formed within the element isolation part STI. A bottom surface of the trench Tr is deeper than the interface IF. A structure shown in FIG. 6A is obtained by removing the masking material 70.

The intermediate dielectric film 30 is then deposited on an internal wall of the trench Tr as shown in FIG. 6B. The intermediate dielectric film 30 is a silicon oxide film, for example.

A material of the control gate CG is then deposited on the intermediate dielectric film 30, and this material is flattened as shown in FIG. 6C. Accordingly, the control gate CG is formed on the floating gate FG via the intermediate dielectric film 30.

Next, the protections films 70 and 71, the interlayer dielectric film 72, the bit line contact BLC, and the source line contact SLC shown in FIG. 2 are formed, thereby completing the NOR flash memory according to the first embodiment.

According to the above manufacturing method, the NOR flash memory according to the first embodiment can be obtained by only adding an etching process of the element isolation part STI to a conventional process after forming the floating gate FG. Therefore, the NOR flash memory according to the first embodiment can be formed without significantly increasing the number of manufacturing processes.

### Modification of First Embodiment

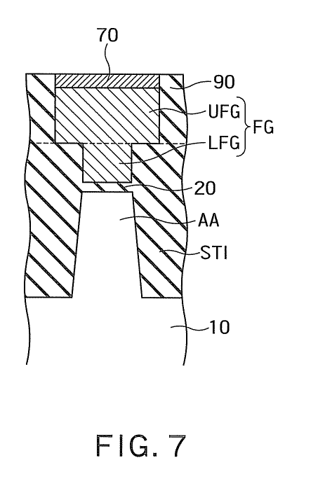

A process shown in FIG. 7 can be added between processes shown in FIG. 5D and FIG. 6A. After performing the process shown in FIG. 5D, an insulation material 90 is deposited on the element isolation part STI and the masking material 70. The insulation material 90 can be the same material as that of the element isolation part STI. The insulation material 90 is flattened until an upper surface of the masking material 70 is exposed by using the CMP. In this case, the masking material 70 functions as a stopper.

Thereafter, the insulation material 90 and the element isolation part STI are anisotropically etched to a deeper position than that of the interface IF by the RIE by using the masking material 70 as a mask. Accordingly, the trench Tr is formed as shown in FIG. 6B. Other manufacturing processes of this modification can be similar to those shown in FIG. 5A to FIG. 6C.

By adding a process of depositing and flattening the insulation material 90, heights of bottom surfaces of plural trenches Tr (depths of the trenches Tr) become constant. Accordingly, a variation of the depth D1 can be decreased by aligning heights of lower ends LEfg of the floating gates FG. This leads to suppress a variation of the coupling ratio between the floating gate FG and the control gate CG.

### Second Embodiment

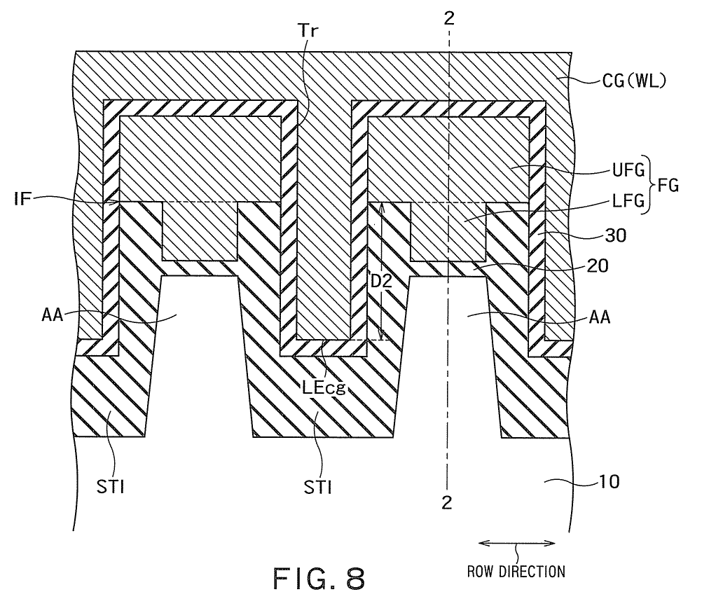

FIG. 8 is a cross-sectional view of a configuration of a NOR flash memory according to a second embodiment. In the second embodiment, the lower end LEcg of the control gate CG is set at a deeper position than a position of the lower end LEfg of the floating gate FG and a position of the upper end of the active area AA. That is, the lower end LEcg of the control gate CG is nearer to the silicon substrate 10 than the lower end LEfg of the lower gate part LFG or the upper end of the active area AA. This means that a height of the lower end LEcg from a surface of the silicon substrate 10 is lower than a height of the lower end LEfg of the lower gate part LFG or the upper end of the active area AA from the surface of the silicon substrate 10. A depth D2 from the interface IF to the lower end LEcg of the control gate CG is larger than D1.

Accordingly, a coupling ratio (Cipd/Cfg) can be increased, and the control gate CG can electrically shield between active areas AA which are adjacent to each other in a row direction. For example, by fixing a voltage of an unselected control gate CG, the control gate CG can prevent an electric disturbance between the active areas AA which are adjacent to each other.

A depth of the lower end LEcg of the control gate CG can be deeper. Accordingly, active areas AA adjacent in a row direction can be more effectively shielded. The lower end LEcg of the control gate CG can be at substantially the same height as that of the lower end LEfg of the floating gate FG or the upper end of the active area AA. Accordingly, the coupling ratio (Cipd/Cfg) can be effectively increased. That is, a high increase rate of the coupling ratio (Cipd/Cfg) can be maintained.

### Third Embodiment

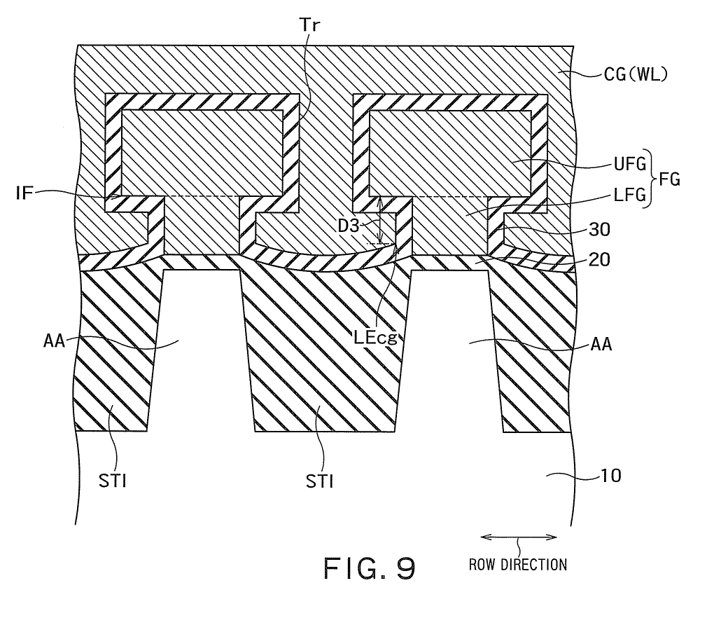

FIG. 9 is a cross-sectional view showing a configuration of a NOR flash memory according to a third embodiment. In the third embodiment, the trench Tr is formed by an isotropic etching of the element isolation part STI. Therefore, the intermediate dielectric film 30 is provided on side surfaces of both the upper gate part UFG and the lower gate part LFG, and is further provided at a part of a bottom surface of the upper gate part UFG. Following this, the control gate CG is provided to face side surfaces of both the upper gate part UFG and the lower gate part LFG via the intermediate dielectric film 30. The control gate CG is provided to also face a part of the bottom surface of the upper gate part UFG via the intermediate dielectric film 30. A recess portion is provided on a top surface of the element isolation part STI between the floating gates FG adjacent to each other. The intermediate dielectric film 30 is also provided on a surface of the recess portion. A part of the control gate CG is provided on a surface of the recess portion on the STI via the intermediate dielectric film 30. Other configurations in the third embodiment can be similar to those in the first embodiment. A depth D3 from the interface IF to the lower end LEcg of the control gate CG can be equal to or larger than D1. So long as the control gate CG faces a part of the bottom surface of the upper gate part UFG and a side surface of the lower gate part LFG, there is no problem when a void is formed within the control gate CG between adjacent lower gate parts LFG.

Because the control gate CG faces a part of the bottom surface of the upper gate part UFG and a side surface of the lower gate part LFG, an opposing area of the control gate CG and the floating gate FG further increases. Therefore, the coupling ratio (Cipd/Cfg) can be further increased.

In the third embodiment, the element isolation part STI can be isotropically etched when forming the trench Tr. Other manufacturing processes in the third embodiment can be similar to those in the first embodiment.

### Fourth Embodiment

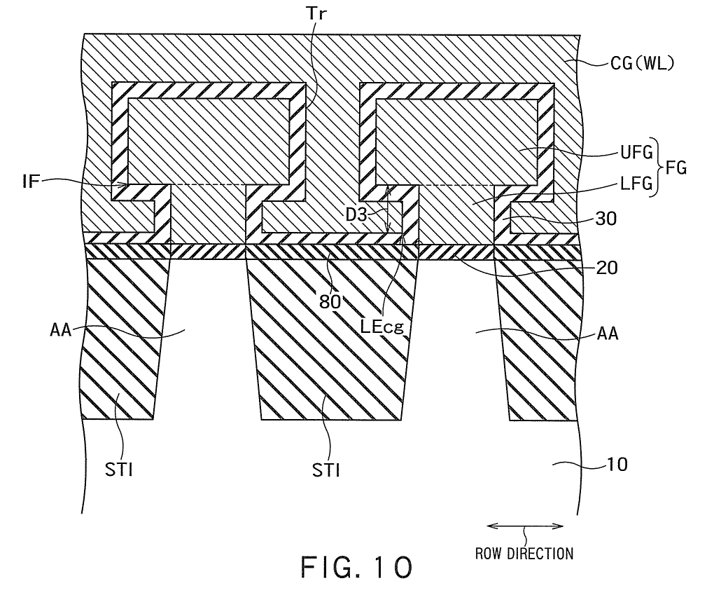

FIG. 10 is a cross-sectional view showing a configuration of a NOR flash memory according to a fourth embodiment. In the fourth embodiment, a stopper film 80 is provided below the control gate CG between the gate parts LFG which are adjacent to each other. The stopper film 80 is provided between the intermediate dielectric film 30 below the control gate CG and the element isolation part STI.

The stopper film 80 functions as a stopper of an isotropic etching when forming the trench Tr. Accordingly, the element isolation part STI in contact with a part of a bottom surface of the upper gate part UFG and a side surface of the lower gate part LFG can be securely removed while keeping a distance between the control gate CG and the active area AA. Because a material of the element isolation part STI is not left at a part of a bottom surface of the upper gate part UFG and on a side surface of the lower gate part LFG, a coupling ratio between the control gate CG and the floating gate FG can be stabilized.

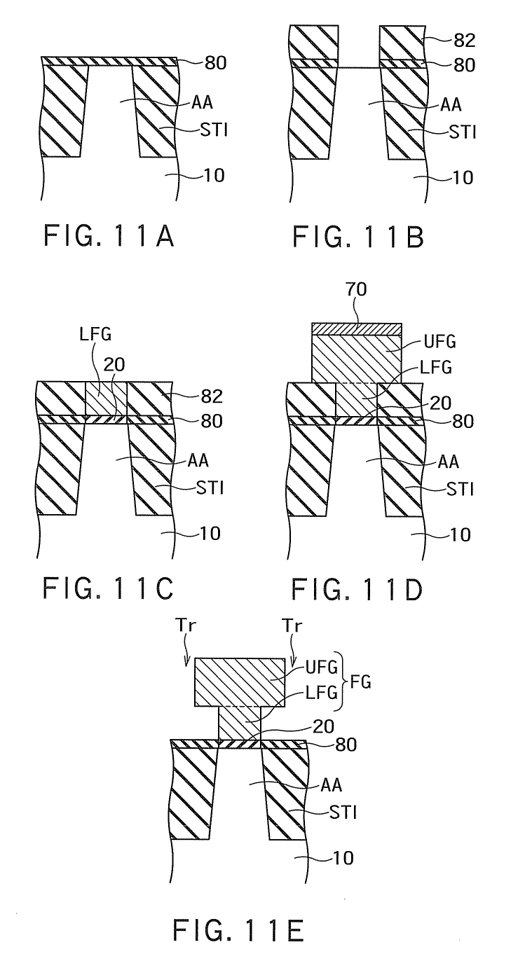

FIG. 11A to FIG. 11E are cross-sectional views showing a manufacturing method of the NOR flash memory according to the fourth embodiment. After the active area AA is formed on the surface of the silicon substrate 10, a material of the element isolation part STI is deposited. The material of the element isolation part STI is polished, thereby flattening the surface of the element isolation part STI. The stopper film 80 is deposited on the material of the element isolation part STI. A material of the stopper 80 is a silicon nitride film, for example. Accordingly, a structure shown in FIG. 11A is obtained.

A sacrificial dielectric film 82 is then deposited on the stopper film 80. The sacrificial dielectric film 82 can be the same material (a silicon oxide film) as that of the element isolation part STI, for example. The sacrificial dielectric film 82 and the stopper film 80 on the active area AA are removed by using the lithography and the RIE, thereby obtaining a structure shown in FIG. 11B.

Next, the tunnel dielectric film 20 and the lower gate part LFG are formed as explained with reference to FIG. 5A, thereby obtaining the structure shown in FIG. 11C. The upper gate part UFG is formed as explained with reference to FIG. 5B to FIG. 5D, thereby obtaining a structure shown in FIG. 11D.

The sacrificial dielectric film 82 is then selectively etched by an isotropic etching as shown in FIG. 11E. In this case, the stopper film 80 functions as a stopper, and the sacrificial dielectric film 82 below the upper gate part UFG can be completely removed. That is, overetching time can be increased by providing the stopper film 80.

Thereafter, the intermediate dielectric film 30 and the control gate CG are formed as explained with reference to FIG. 6B and FIG. 6C, thereby obtaining a structure shown in FIG. 10.

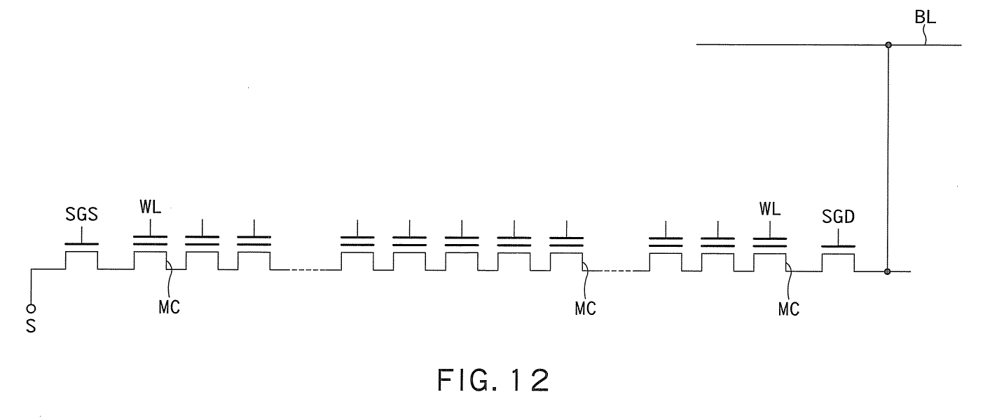

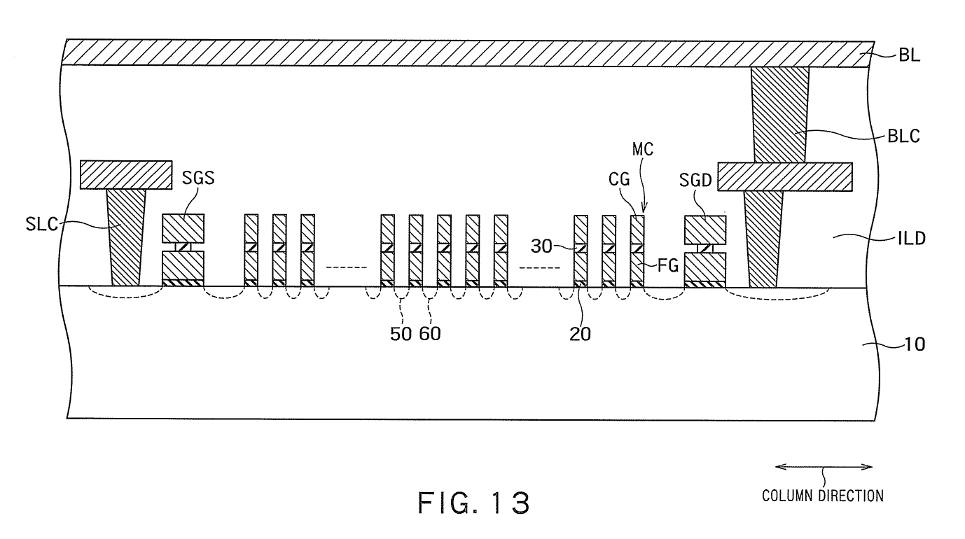

The NOR flash memory is explained in the first to fourth embodiments above. The first to fourth embodiments can be also applied to a NAND flash memory shown in FIG. 12 and FIG. 13. In the case of the NAND flash memory, a source line contact and a bit line contact are not provided at both sides of the memory cell MC. Therefore, the floating gates FG are adjacent via an interlayer dielectric film ILD on a cross-sectional surface in a column direction as shown in FIG. 13. Consequently, in the case of the NAND flash memory, a capacitance between the floating gates FG of memory cells adjacent in a column direction increases.

In the first to fourth embodiments, a coupling ratio between the floating gate FG and the control gate CG can be increased without increasing an area of a side surface of the floating gate FG. The first to fourth embodiments can be also applied to the NAND flash memory. In this case, the NAND flash memory can obtain respective effects of the first to fourth embodiments. When the first to fourth embodiments are applied to the NAND flash memory, cross-sectional surfaces thereof in a row direction are similar to those in FIG. 3, FIG. 8, or FIG. 9.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and sprit of the invention.

1. A semiconductor memory device comprising:
a plurality of active areas on a surface of a semiconductor substrate;
an element isolation part between the active areas adjacent to each other;
a tunnel dielectric film on each of the active areas;
a plurality of floating gates each comprising a lower gate part facing a corresponding one of the active areas via the tunnel dielectric film and an upper gate part having a larger width than that of the lower gate part on a cross-sectional surface perpendicular to an extension direction of the active area, the upper gate part being on the lower gate part;
an intermediate dielectric film on an upper surface and on a side surface of each of the floating gates; and
a control gate on an upper surface and on a side surface of at least each of the floating gates via the intermediate dielectric film, wherein
a height of a lower end of the control gate from a surface of the semiconductor substrate is lower than a height of an interface between the upper gate part and the lower gate part from the surface of the semiconductor substrate.

2. The device of claim 1, wherein the control gate protrudes into the inside of the element isolation part between the floating gates adjacent to each other.

3. The device of claim 1, further comprising:
a recess portion on a top surface of the element isolation part between the floating gates adjacent to each other, wherein
the intermediate dielectric film is provided on a surface of the recess portion.

4. The device of claim 3, wherein a part of the control gate is provided on a surface of the recess portion via the intermediate dielectric film.

5. The device of claim 1, further comprising:
a bit line contact adjacent to one side surface of the floating gate in an extension direction of the active area; and
a source line contact adjacent to the other side surface of the floating gate in the extension direction of the active area.

6. The device of claim 2, further comprising:
a bit line contact adjacent to one side surface of the floating gate in an extension direction of the active area; and
a source line contact adjacent to the other side surface of the floating gate in the extension direction of the active area.

7. The device of claim 1, wherein a bottom side of the lower gate part has a width substantially equal to that of an upper side of the active area on a cross-sectional surface in a direction perpendicular to the extension direction of the active area.

8. The device of claim 1, wherein the floating gate has a T shape on a cross-sectional surface in a direction perpendicular to the extension direction of the active area.

9. The device of claim 1, wherein a distance from a lower end of the control gate to the semiconductor substrate is smaller than a distance from a lower end of the lower gate part to the semiconductor substrate.

10. The device of claim 1, wherein a lower end of the control gate is superior to an interface between the tunnel dielectric film and the lower gate part.

11. The device of claim 10, wherein the control gate protrudes into the inside of the element isolation part between the floating gates adjacent to each other.

12. The device of claim 10, further comprising:
a recess portion on a top surface of the element isolation part between the floating gates adjacent to each other, wherein
the intermediate dielectric film is provided on a surface of the recess portion.

13. The device of claim 12, wherein a part of the control gate is provided on a surface of the recess portion via the intermediate dielectric film.

14. The device of claim 10, further comprising:
a bit line contact adjacent to one side surface of the floating gate in an extension direction of the active area; and
a source line contact adjacent to the other side surface of the floating gate in the extension direction of the active area.

15. The device of claim 11, further comprising:
a bit line contact adjacent to one side surface of the floating gate in an extension direction of the active area; and
a source line contact adjacent to the other side surface of the floating gate in the extension direction of the active area.

16. The device of claim 10, wherein a bottom side of the lower gate part has a width substantially equal to that of an upper side of the active area on a cross-sectional surface in a direction perpendicular to the extension direction of the active area.

17. The device of claim 10, wherein the floating gate has a T shape on a cross-sectional surface in a direction perpendicular to the extension direction of the active area.

18. The device of claim 11, wherein
the intermediate dielectric film is provided on both side surfaces of the upper gate part and on both side surfaces of the lower gate part, and
the control gate faces both side surfaces of the upper gate part and on both side surfaces of the lower gate part via the intermediate dielectric film.

19. A manufacturing method of a semiconductor memory device, comprising:
forming a plurality of active areas on a surface of a semiconductor substrate;
forming an element isolation part between the active areas adjacent to each other;
forming a tunnel dielectric film on the active areas;
forming a lower gate part on the tunnel dielectric film, the lower gate part being a part of a floating gate;
depositing a material of an upper gate part on the lower gate part and on the element isolation part, the upper gate part being a part of the floating gate;
depositing a masking material on a material of the upper gate part;
patterning the masking material and the material of the upper gate part so that the upper gate part has larger width than that of the lower gate part on a cross-sectional surface perpendicular to an extension direction of the active area;
forming a trench within the element isolation part by etching the element isolation part to a deeper position than an interface between the upper gate part and the lower gate part by using the masking material as a mask;
forming an intermediate dielectric film on an internal wall of the trench; and
depositing a material of a control gate on the intermediate dielectric film, wherein
a height of a lower end of the control gate from a surface of the semiconductor substrate is lower than a height of the interface between the upper gate part and the lower gate part from the surface of the semiconductor substrate.

20. The method of claim 19, further comprising:
depositing an insulation material on the element isolation part and the masking material, after patterning the masking material and the material of the upper gate part; and
flattening the insulation material by using the masking material as a stopper,
thereafter, forming the trench.
